(19) United States
(12) Patent Application Publication
(10) Pub. No.: US 2003/0156390 A1
(43) Pub. Date: Aug. 21, 2003

(54) Wireless LAN card with efficient productivity

(75) Inventors: Hideki Takeshita, Fukushima-ken (JP); Toru Izumiyama, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/365,342

(22) Filed: Feb. 12, 2003

(30) Foreign Application Priority Data
Feb. 15, 2002 (JP) 2002-038649

(51) Int. Cl. H05K 1/14

(52) U.S. Cl. 361/737

(57) ABSTRACT

A wireless LAN (local area network) card includes a circuit board having a plurality of connector terminals; a transmission and reception circuit formed on a surface of the circuit board; a baseband circuit formed on the surface; a non-volatile memory mounted on the surface; and a box-shaped cover for covering the transmission and reception circuit. The non-volatile memory is disposed in the vicinity of the transmission and reception circuit so that the transmission and reception circuit and the non-volatile memory are covered by the cover. The wireless LAN card requires no coating resin, and is therefore efficient in usability and cost.

### BACKGROUND OF THE INVENTION

1. Field of the Invention

The present invention relates to a wireless LAN (local area network) card for use in wireless data communication between electronic devices such as personal computers.

2. Description of the Related Art

FIG. 2 is a schematic perspective view of a wireless LAN card of the related art, and FIG. 3 is a schematic perspective view of the wireless LAN card, as viewed from the reverse side.

The structure of a wireless LAN card of the related art is described below with reference to FIGS. 2 and 3. A circuit board 51 formed of laminated substrates has a wiring pattern 52 formed on both a surfaces 51a and the opposite surface 51b thereof, and also has a plurality of connector terminals 53 arranged at one end thereof on both the surfaces 51a and 51b.

Various electric parts (not shown) are mounted on the surface 51a of the circuit board 51 to form a transmission and reception circuit 54 including an RF circuit.

A box-shaped cover 55 formed by folding a metal plate is attached to the surface 51a of the circuit board 51 so as to cover the transmission and reception circuit 54.

Meanwhile, a non-volatile memory 56 and various electric parts (not shown) are mounted on the opposite surface 51b of the circuit board 51 to form a baseband circuit 57 for processing a signal from the transmission and reception circuit 54.

The non-volatile memory 56 is an erasable and rewritable memory, and is coated with a coating resin 58 made of an insulating material so as to prevent the nonvolatile memory 56 from being easily detached from the circuit board 51 to alter data.

The thus constructed wireless LAN card is attachable and detachable to and from a personal computer. When the wireless LAN card is attached to a personal computer, the terminals 53 are connected with connectors (not shown) to allow for wireless data transmission and reception to and from another personal computer.

The wireless LAN card of the related art requires the coating resin 58 to coat the non-volatile memory 56, and is therefore inefficient in productivity and cost.

While the wireless LAN card of the related art is compact since the transmission and reception circuit 54 and the baseband circuit 57 are formed on opposite surfaces (51a and 51b) of the circuit board 51, various electric parts must be mounted on both surfaces of the circuit board 51, leading to inefficiency in manufacturability and cost.

### SUMMARY OF THE INVENTION

Accordingly, it is an object of the present invention to provide an inexpensive wireless LAN card with better productivity and manufacturability.

The foregoing object is achieved by the present invention through the provision of a wireless LAN card including a circuit board having a plurality of connector terminals; a transmission and reception circuit formed on a surface of the circuit board; a baseband circuit formed on the surface of the circuit board; a non-volatile memory mounted on the surface of the circuit board; and a box-shaped cover for covering the transmission and reception circuit. The non-volatile memory is disposed in the vicinity of the transmission and reception circuit so that the transmission and reception circuit and the non-volatile memory are covered by the cover.

Therefore, there is no need for a coating resin used in a wireless LAN card of the related art, thus achieving a high usability inexpensive wireless LAN card. The transmission and reception circuit and the baseband circuit are formed on the same surface of the circuit board, thus achieving an inexpensive wireless LAN card with efficient manufacturability.

The cover may include a first cover portion for covering the transmission and reception circuit, and a second cover portion smaller than the first cover portion for covering the non-volatile memory. The second cover portion projects from a side of the first cover portion. Therefore, the material efficiency of the cover is improved, thus reducing the material cost and making the wireless LAN card compact.

The circuit board may be partitioned into a first region and a second region. The transmission and reception circuit may be formed in the first region, and the baseband circuit may be formed in the second region. This can make the circuit structure simple, thus increasing the productivity.

A grounded conductive pattern may be formed between the transmission and reception circuit and the baseband circuit on the surface of the circuit board, and a sidewall of the cover which is located between the transmission and reception circuit and the baseband circuit may be coupled to the grounded conductive pattern so as to be grounded. This allows the cover to be grounded and also allows the transmission and reception circuit and the baseband circuit to be successfully shielded from each other.

The surface of the circuit board may include a grounded area in which the grounded conductive pattern is formed, and a wired area in which the transmission and reception circuit is electrically connected with the baseband circuit. The grounded area and the wired area may be disposed side-by-side across the circuit board, and the wired area may be disposed at one side end of the circuit board. This allows the transmission and reception circuit and the baseband circuit to be successfully shielded from each other and easily connected with each other.

The connector terminals may be disposed at one end of the circuit board close to the baseband circuit. This allows the wiring from the baseband circuit to the terminals to be simple.

### BRIEF DESCRIPTION OF THE DRAWINGS

FIG. 1 is a schematic perspective view of a wireless LAN card of the present invention;

FIG. 2 is a schematic perspective view of a wireless LAN card of the related art; and

FIG. 3 is a schematic perspective view of the wireless LAN card of the related art, as viewed from the reverse side.

### DESCRIPTION OF THE PREFERRED EMBODIMENTS

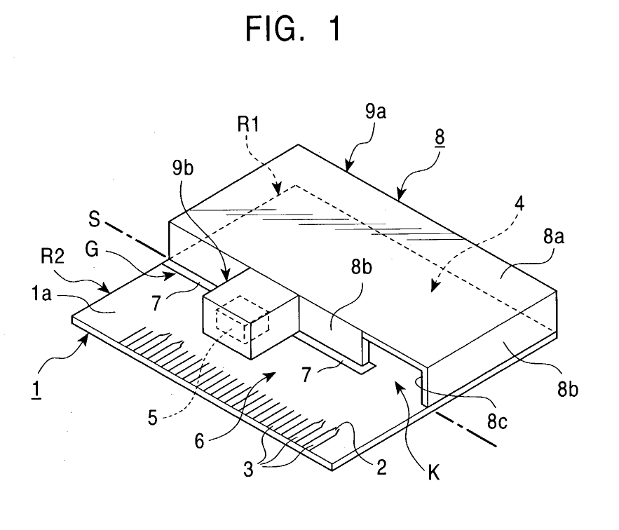

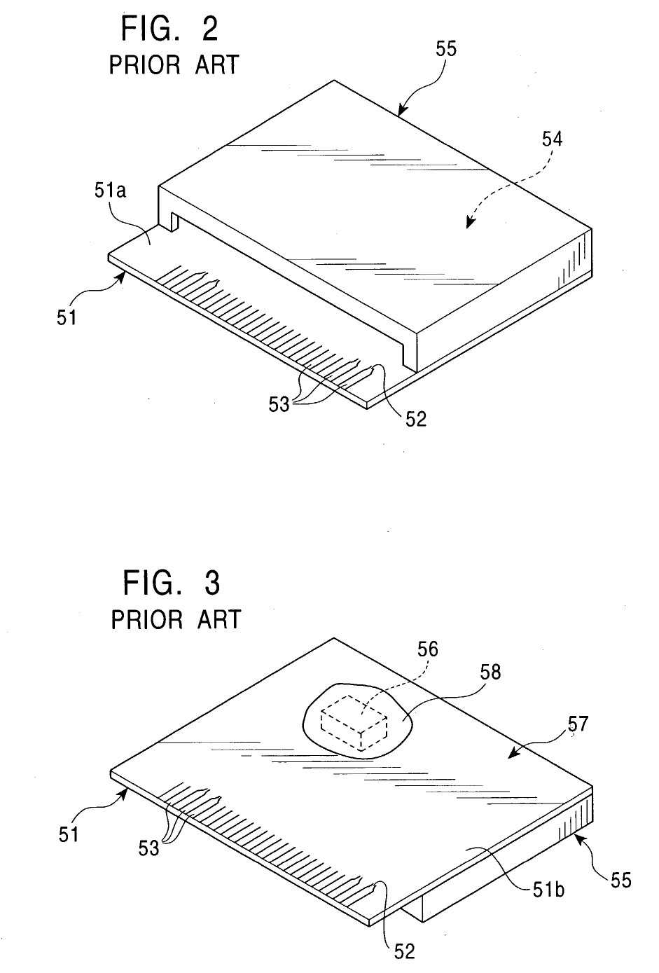

FIG. 1 is a schematic perspective view of a wireless LAN card of the present invention.

The structure of a wireless LAN card of the present invention is described below with reference to FIG. 1. A circuit board 1 formed of laminated substrates has a wiring pattern 2 formed on a surface 1a thereof, and also has a plurality of connector terminals 3 arranged at one end thereof on both the surface 1a and the opposite surface 1b.

The surface 1a of the circuit board 1 is partitioned by an imaginary line S which crosses the circuit board 1 into a first region R1 and a second region R2. In the first region R1, various electric parts (not shown) are mounted to form a transmission and reception circuit 4 including an RF circuit. In the second region R2, a non-volatile memory 5 and various electric parts (not shown) are mounted to form a baseband circuit 6 for processing a signal from the transmission and reception circuit 4.

The connector terminals 3 are arranged at one end of the circuit board 1 in the second region R2 in which the baseband circuit 6 is formed.

A grounded strip conductive pattern 7 used for grounding is formed between the transmission and reception circuit 4 and the baseband circuit 6 in a grounded area G positioned along the line S on the surface 1a of the circuit board 1.

The grounded conductive pattern 7 formed on the surface 1a starts from the one side end toward the center of the circuit board 1, and terminates midway so that the leading end of the conductive pattern 7 does not reach the opposite side end.

A portion positioned along the line S in which the grounded conductive pattern 7 is not formed is referred to as a wired area K. The wiring pattern 2 is formed in the wired area K so that the transmission and reception circuit 4 is electrically connected with the baseband circuit 6.

A box-shaped cover 8 formed by folding a metal plate has a top wall 8a, sidewalls 8b folded downward from the top wall 8a, and a cutout portion 8c formed in one of the sidewalls 8b.

The cover 8 is formed of a first box-shaped cover portion 9a, and a second box-shaped cover portion 9b which is smaller than the first cover portion 9a, and the second box-shaped cover portion 9b projects from a side of the first cover portion 9a.

The non-volatile memory 5 is incorporated in the baseband circuit 6 disposed in the vicinity of the transmission and reception circuit 4 across the grounded conductive pattern 7. The cover 8 is attached to the surface 1a of the circuit board 1 in such a manner that the transmission and reception circuit 4 is covered by the first cover portion 9a and the non-volatile memory 5 is covered by the second cover portion 9b.

The sidewall 8b which includes the cutout portion 8c and which forms a part of the first cover portion 9a stands on the conductive pattern 8, and this sidewall 8b is bonded to the conductive pattern 7 by soldering so as to make the cover 8 grounded. This sidewall 8b also allows the transmission and reception circuit 4 and the baseband circuit 6 to be shielded from each other.

The cutout portion 8c which is positioned in the wired area K when the cover 8 is attached to the surface 1a of the circuit board 1 allows the transmission and reception circuit 4 and the baseband circuit 6 to be electrically connected with each other.

The non-volatile memory 5 is an erasable and rewritable memory. The non-volatile memory 5 is covered by the cover 8, and is not easily detachable from the circuit board 1 to prevent alteration of data.

The thus constructed wireless LAN card is attachable and detachable to and from a personal computer. When the wireless LAN card is attached to a personal computer, the terminals 3 are connected with connectors (not shown) to allow for wireless data transmission and reception to and from another personal computer.

What is claimed is:

1. A wireless LAN card comprising:
a circuit board having a plurality of connector terminals;
a transmission and reception circuit formed on a surface of the circuit board;
a baseband circuit formed on the surface of the circuit board;
a non-volatile memory mounted on the surface of the circuit board; and
a box-shaped cover for covering the transmission and reception circuit,
wherein the non-volatile memory is disposed in the vicinity of the transmission and reception circuit so that the transmission and reception circuit and the non-volatile memory are covered by the cover.

2. A wireless LAN card according to claim 1, wherein the cover includes a first cover portion for covering the transmission and reception circuit, and a second cover portion smaller than the first cover portion for covering the non-volatile memory, the second cover portion projecting from a side of the first cover portion.

3. A wireless LAN card according to claim 1, wherein the circuit board is partitioned into a first region and a second region, the transmission and reception circuit is formed in the first region, and the baseband circuit is formed in the second region.

4. A wireless LAN card according to claim 3, wherein a grounded conductive pattern is formed between the transmission and reception circuit and the baseband circuit on the surface of the circuit board, and a sidewall of the cover which is located between the transmission and reception circuit and the baseband circuit is coupled to the grounded conductive pattern so as to be grounded.

5. A wireless LAN card according to claim 4, wherein the surface of the circuit board includes a grounded area in which the grounded conductive pattern is formed, and a wired area in which the transmission and reception circuit is electrically connected with the baseband circuit, the grounded area and the wired area is disposed side-by-side across the circuit board, and the wired area is disposed at one side end of the circuit board.

6. A wireless LAN card according to claim 1, wherein the connector terminals are disposed at one end of the circuit board close to the baseband circuit.
